(19) United States
(12) Patent Application Publication
(10) Pub. No.: US 2025/0158263 A1
(43) Pub. Date: May 15, 2025

(54) WAVEGUIDE DEVICE

(71) Applicant: NGK INSULATORS, LTD., Nagoya-shi (JP)

(72) Inventors: Kentaro TANI, Nagoya-shi (JP); Jungo KONDO, Miyoshi-shi (JP)

(21) Appl. No.: 19/023,830

(22) Filed: Jan. 16, 2025

Related U.S. Application Data
(63) Continuation of application No. PCT/JP2023/020933, filed on Jun. 6, 2023.

(30) Foreign Application Priority Data
Jul. 22, 2022 (JP) 2022-117271

(51) Int. Cl. H01P 3/00

(52) U.S. Cl. CPC H01P 3/003

(57) ABSTRACT

A waveguide device is configured to guide an electromagnetic wave having a frequency of 30 GHz or more and 20 THz or less. The waveguide device includes: a resin material substrate; a conductor layer provided on the resin material substrate; and a support substrate positioned on a side opposite from the conductor layer with respect to the resin material substrate. The resin material substrate and the support substrate are directly joined to each other.

### CROSS-REFERENCE TO RELATED APPLICATIONS

This application is a continuation application of PCT/JP2023/020933, filed on Jun. 6, 2023, which claims the benefit of Japanese Application No. 2022-117271, filed on Jul. 22, 2022, the entire contents of which are incorporated herein by reference.

### BACKGROUND OF THE INVENTION

### 1. Field of the Invention

The present invention relates to a waveguide device.

### 2. Description of the Related Art

As one of devices for guiding a millimeter wave/terahertz wave, a waveguide device is being developed. The waveguide device is expected to find applications across a wide range of fields, such as optical waveguides, next-generation high-speed communications, sensors, laser processing, and solar power generation. As a waveguide device, a mode converter has been proposed. The mode converter includes, for example: an upper substrate which functions as a flexible substrate; a planar circuit which is provided on the upper substrate to serve as a connection portion for high-frequency signal propagation; and a substrate having a ground conductor layer provided on a front surface and a back surface. The mode converter is provided with the upper substrate and the substrate bonded together by an adhesive layer formed from an organic adhesive such as epoxy resin (see Patent Literature 1).

### CITATION LIST

### Patent Literature

[PTL 1] JP 2014-236291 A

### SUMMARY OF THE INVENTION

However, it is difficult for the mode converter as described in Patent Literature 1 to reduce thermal resistance of an adhered portion because the upper substrate and the substrate are adhered to each other with an organic adhesive. Accordingly, when an active device (for example, an oscillator or a receiver) is mounted to this type of mode converter, the upper substrate may be heated due to a failure to dissipate heat transferred to the upper substrate from the active device. In this case, the heat may be transferred to other members connected to the upper substrate (for example, other active devices or mounted parts) to degrade characteristics of those members.

A primary object of the present invention is to provide a waveguide device capable of supporting a resin material substrate by a support substrate as well as reducing thermal resistance.

[1] A waveguide device according to one embodiment of the present invention is configured to guide an electromagnetic wave having a frequency of 30 GHz or more and 20 THz or less. The waveguide device may include: a resin material substrate; a conductor layer provided on the resin material substrate; and a support substrate positioned on a side opposite from the conductor layer with respect to the resin material substrate. In some embodiments, the resin material substrate and the support substrate are directly joined to each other.

[2] The waveguide device according to the above-mentioned item [1] may further include a first ground electrode positioned between the resin material substrate and the support substrate.

[3] In some configurations of the waveguide device according to the above-mentioned item [2], the first ground electrode may be in direct contact with the resin material substrate and the support substrate to function as a joining portion for joining the resin material substrate and the support substrate to each other.

[4] In some configurations of the waveguide device according to the above-mentioned item [2], the first ground electrode may be in direct contact with the resin material substrate, and the waveguide device may further include a joining portion for joining the first ground electrode and the support substrate to each other.

[5] In some configurations of the waveguide device according to the above-mentioned item [2], the first ground electrode may be in direct contact with the support substrate, and the waveguide device may further include a joining portion for joining the resin material substrate and the first ground electrode to each other.

[6] In some configurations of the waveguide device according to any one of the above-mentioned items [1] to [5], the conductor layer may include: a signal electrode which forms a transmission line configured to propagate the electromagnetic wave; and a second ground electrode arranged at a distance from the signal electrode.

[7] The waveguide device according to the above-mentioned item [6] may further include a third ground electrode, a first via, and a second via. The third ground electrode is positioned on a side opposite from the first ground electrode with respect to the support substrate. The first via electrically connects the second ground electrode and the third ground electrode, and is electrically connected to the first ground electrode. The second via may electrically connect the first ground electrode and the second ground electrode. The first via may include a plurality of first vias, and the second via may be arranged between two first vias adjacent to each other out of the plurality of first vias.

[8] The waveguide device according to the above-mentioned item [6] may further include a third ground electrode and a plurality of through-substrate vias. The third ground electrode may be positioned on a side opposite from the first ground electrode with respect to the support substrate. The plurality of through-substrate vias may electrically connect the first ground electrode and the third ground electrode. The first ground electrode, the third ground electrode, and the plurality of through-substrate vias may form a substrate-integrated waveguide configured to propagate the electromagnetic wave.

[9] In some configurations of the waveguide device according to any one of the above-mentioned items [1] to [8], the resin material substrate may have a thickness “t” which satisfies Formula (1):

$$t < \frac{λ}{a \sqrt{ε}} \qquad ( 1 )$$

where “t” represents the thickness of the resin material substrate, λ represents a wavelength of the electromagnetic wave guided by the waveguide device, c represents a relative dielectric constant of the resin material substrate at 150 GHz, and “a” represents a numerical value of 3 or more.

[10] In some configurations of the waveguide device according to the above-mentioned item [9], in Formula (1), “a” may represent a numerical value of 6 or more.

[11] In some configurations of the waveguide device according to any one of the above-mentioned items [1] to [10], the resin material substrate may have a thickness “t” which is 100 μm or less.

[12] In some configurations of the waveguide device according to any one of the above-mentioned items [1] to [11], the resin material substrate may have a thickness “t” which is 1 μm or more.

[13] The waveguide device according to the above-mentioned item [1] or [2] may further include a joining portion. The joining portion may be provided between the resin material substrate and the support substrate. The joining portion may be a SiO₂ layer, an amorphous silicon layer, or a tantalum oxide layer.

According to the embodiments of the present invention, the waveguide device capable of supporting the resin material substrate by the support substrate as well as reducing thermal resistance can be achieved.

### BRIEF DESCRIPTION OF THE DRAWINGS

FIG. 1 is a schematic perspective view of a waveguide device according to one embodiment of the present invention.

FIG. 2 is a cross-sectional view of the waveguide device taken along the line II-II′ of FIG. 1.

FIG. 3 is a schematic cross-sectional view for illustrating an example of arrangement of a joining portion in the waveguide device of FIG. 2.

FIG. 4 is a schematic cross-sectional view for illustrating another example of the arrangement of the joining portion in the waveguide device of FIG. 2.

FIG. 5 is a schematic cross-sectional view for illustrating still another example of the arrangement of the joining portion in the waveguide device of FIG. 2.

FIG. 6 is a schematic perspective view for illustrating a modification example of the waveguide device of FIG. 1.

FIG. 7 is a cross-sectional view of the waveguide device taken along the line VII-VII′ of FIG. 6.

FIG. 8 is a schematic perspective view of a waveguide device according to another embodiment of the present invention.

FIG. 9 is a cross-sectional view of the waveguide device taken along the line IX-IX′ of FIG. 8.

FIG. 10 is a cross-sectional view of the waveguide device taken along the line X-X′ of FIG. 8.

FIG. 11 is a cross-sectional view of the waveguide device taken along the line XI-XI′ of FIG. 8.

FIG. 12 is a schematic cross-sectional view for illustrating a modification example of a shape of a via in the waveguide device of FIG. 9.

FIG. 13 is a schematic cross-sectional view for illustrating a modification example of arrangement of vias in the waveguide device of FIG. 12.

FIG. 14 is a schematic cross-sectional view for illustrating another modification example of arrangement of vias in the waveguide device of FIG. 9.

FIG. 15 is a schematic perspective view of a waveguide device according to still another embodiment of the present invention.

FIG. 16 is a cross-sectional view of the waveguide device taken along the line XVI-XVI′ of FIG. 15.

FIG. 17 is a schematic perspective view of a waveguide device according to yet still another embodiment of the present invention.

FIG. 18 is a cross-sectional view of the waveguide device taken along the line XVIII-XVIII′ of FIG. 17.

FIG. 19 is an exploded perspective view of the waveguide device of FIG. 17.

FIG. 20 is a schematic cross-sectional view for illustrating a state in which a conductor pin of FIG. 17 is covered with an insulating material.

FIG. 21 is a schematic perspective view of a waveguide device according to yet still another embodiment of the present invention.

FIG. 22 is a cross-sectional view of the waveguide device taken along the line XXII-XXII′ of FIG. 21.

FIG. 23 is a schematic cross-sectional view of a waveguide device according to yet still another embodiment of the present invention.

FIG. 24 is a schematic cross-sectional view for illustrating a modification example of the waveguide device of FIG. 23.

### DESCRIPTION OF THE EMBODIMENTS

Embodiments of the present invention are described below. However, the present invention is not limited to these embodiments.

### A. Overall Configuration of Waveguide Device 100

### A-1. Overall Configuration of Waveguide Device 100

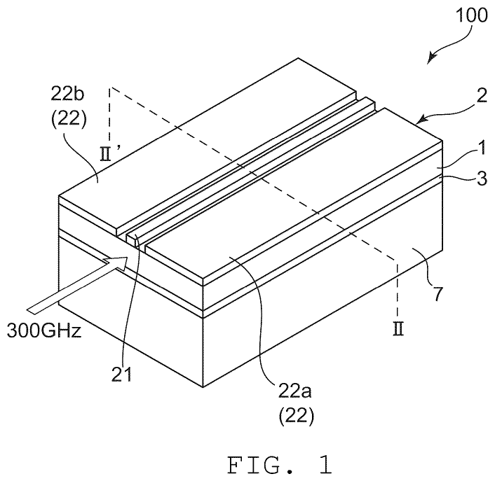

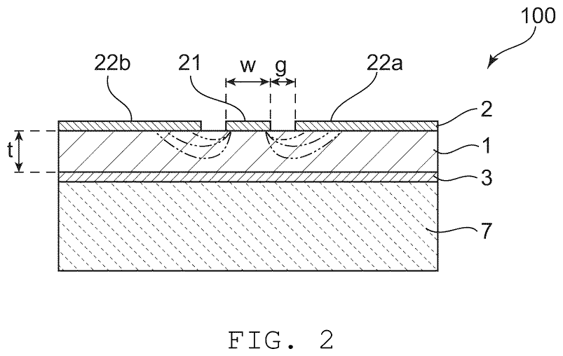

FIG. 1 is a schematic perspective view of a waveguide device 100 according to one embodiment of the present invention, and FIG. 2 is a cross-sectional view of the waveguide device 100 taken along the line II-II′ of FIG. 1.

A waveguide device 100 of the illustrated example is capable of guiding an electromagnetic wave having a frequency of 30 GHz or more and 20 THz or less, i.e., an electromagnetic wave that is a millimeter wave/terahertz wave. The “millimeter wave” is typically an electromagnetic wave having a frequency of from about 30 GHz to about 300 GHz, and the “terahertz wave” is typically an electromagnetic wave having a frequency of from about 300 GHz to about 20 THz.

The waveguide device 100 includes a resin material substrate 1, a conductor layer 2, and a support substrate 7. The conductor layer 2 is provided on the resin material substrate 1. The support substrate 7 is positioned on a side opposite from the conductor layer 2 with respect to the resin material substrate 1. In some embodiments, the resin material substrate 1 and the support substrate 7 are directly joined to each other. The support substrate 7 thus supports the resin material substrate 1, enhancing the mechanical strength of the waveguide device 100.

The phrase “directly joined” as used herein means that two layers or substrates are joined to each other without the interposition of an organic adhesive (e.g., an adhesive such as a resin). The form of the direct joining may be appropriately set in accordance with the configurations of the layers or the substrates to be joined to each other. Further, an interface joined by the direct joining is typically amorphized. Accordingly, the thermal resistance of the joining interface can be dramatically reduced as compared to resin adhesion (resin joining) with the organic adhesive. Thus, in the case where an active device (e.g., an oscillator or a receiver) is mounted on the waveguide device 100, even when heat generated from the active device is transferred to the resin material substrate 1, such heat can be smoothly caused to escape from the resin material substrate 1 to a package through the support substrate 7. As a result, the heating of the resin material substrate 1 can be suppressed, and hence the degradation of the characteristics of any other member (e.g., any other active device or mounted part) to be connected to the resin material substrate 1 can be suppressed. The form of the direct joining may also include joining the support substrate 7 and the resin material substrate 1 via a first ground electrode 3 and/or a joining portion 8 as described later.

Further, when the resin material substrate 1 and the support substrate 7 are integrated by the direct joining, peeling within the waveguide device 100 can be effectively reduced. As a result damages (e.g., a crack) to the resin material substrate 1 from peeling can be suppressed.

The direct joining may be achieved by, for example, the following procedure. In a high-vacuum chamber (e.g., approximately 1×10⁻⁶ Pa), the joining surface of each of components (layers or substrates) to be joined to each other is irradiated with a neutralized beam. Thus, each joining surface is activated. Then, in a vacuum atmosphere, the activated joining surfaces are brought into contact with each other, and are joined to each other at normal temperature. The load applied during joining may range, for example, from 100 N to 20,000 N. In one embodiment, when the surface activation with a neutralized beam is performed, an inert gas is introduced into a chamber, and a high voltage is applied from a DC power source to an electrode positioned in the chamber. With such configuration, an electric field generated between the electrode (positive electrode) and the chamber (negative electrode) causes electrons to move, generating atomic and ion beams derived from the inert gas. Among the beams that have reached a grid, the ion beam is neutralized at the grid, and hence a beam of neutral atoms is emitted from a high-speed atomic beam source. An atomic species for forming the beam is preferably an inert gas element (e.g., argon (Ar) or nitrogen (N)). At the time of the activation by beam irradiation, a voltage is, for example, from 0.5 kV to 2.0 kV, and a current is, for example, from 50 mA to 200 mA. The method for direct joining is not limited to this procedure, and, for example, a surface activation method using a fast atom beam (FAB) or an ion gun, an atomic diffusion method, or a plasma joining method may be applied.

In one embodiment, the waveguide device 100 includes the first ground electrode 3 positioned between the resin material substrate 1 and the support substrate 7. The first ground electrode 3 can help reduce leakage of an electric field generated when a voltage is applied to the conductor layer 2 to the support substrate 7 from the resin material substrate 1. Accordingly, substrate resonance and stray capacitance can be suppressed, and a propagation loss can be reduced.

In the illustrated example, the first ground electrode 3 is in direct contact with the resin material substrate 1 and the support substrate 7 to function as a joining portion that joins the resin material substrate 1 and the support substrate 7 together. In this embodiment, the first ground electrode 3 is the only component provided between the resin material substrate 1 and the support substrate 7. That is, the resin material substrate 1 and the support substrate 7 are directly joined to each other only via the first ground electrode 3. This configuration can provide a stable reduction in thermal resistance of the waveguide device 100.

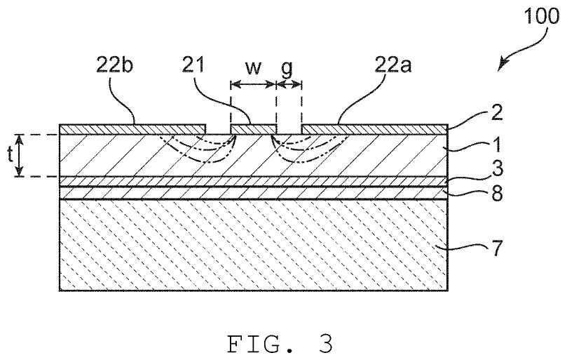

As illustrated in FIG. 3, in one embodiment, the waveguide device 100 further includes the joining portion 8 provided between the resin material substrate 1 and the support substrate 7. The first ground electrode 3 may be formed on a surface of the resin material substrate 1 that is opposite from the conductor layer 2, and may be in direct contact with the resin material substrate 1. In an embodiment illustrated in FIG. 3, the joining portion 8 is positioned between the first ground electrode 3 and the support substrate 7 to join the first ground electrode 3 and the support substrate 7 together.

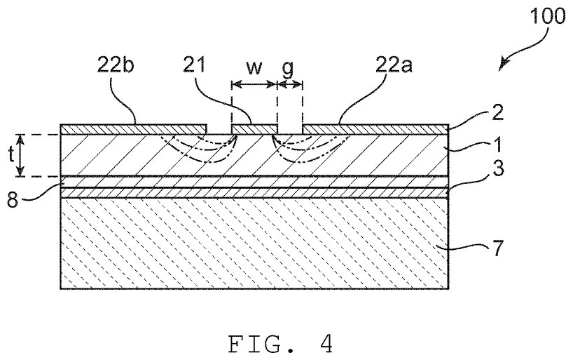

As illustrated in FIG. 4, the first ground electrode 3 may alternatively be formed on a surface of the support substrate 7 that is on a resin material substrate side, and may be in direct contact with the support substrate 7. In an embodiment illustrated in FIG. 4, the joining portion 8 is positioned between the resin material substrate 1 and the first ground electrode 3 to join the resin material substrate 1 and the first ground electrode 3 together.

In the embodiments illustrated in FIGS. 3 and 4, the first ground electrode 3 and the joining portion 8 are provided between the resin material substrate 1 and the support substrate 7. That is, the resin material substrate 1 and the support substrate 7 are directly joined together via the first ground electrode 3 and the joining portion 8. According to these embodiments as well, thermal resistance of the waveguide device 100 can be reduced stably.

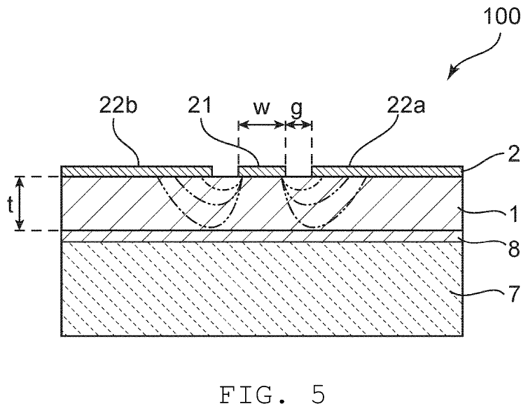

As illustrated in FIG. 5, the first ground electrode 3 may be omitted from the waveguide device 100. In an embodiment illustrated in FIG. 5, the joining portion 8 is positioned between the resin material substrate 1 and the support substrate 7 to join the resin material substrate 1 and the support substrate 7 together. In this embodiment, the joining portion 8 is the only component provided between the resin material substrate 1 and the support substrate 7. That is, the resin material substrate 1 and the support substrate 7 are directly joined to each other only via the joining portion 8. This configuration can provide a stable reduction in thermal resistance of the waveguide device 100.

Similar to those devices, it is preferable that no organic material (e.g., an adhesive) other than the resin material substrate 1 is interposed between the conductor layer 2 and the support substrate 7. Thus, thermal resistance at an interface between the resin material substrate 1 and the support substrate 7 can be reduced, and hence the degradation of the characteristics of an active device or a mounted part can be suppressed. A structure where no organic material (e.g., an adhesive) other than the resin material substrate 1 is interposed is obtained by directly joining the resin material substrate 1 and the support substrate 7 (the first ground electrode may be formed on at least one of the resin material substrate 1 and the support substrate 7, or may not be formed thereon) to each other.

As illustrated in FIGS. 1 and 2, the conductor layer 2 typically includes a signal electrode 21. The signal electrode 21 forms a transmission line along which the electromagnetic waves described above can be propagated. The signal electrode 21 typically has a line shape stretching in a predetermined direction. A width “w” of the signal electrode 21 is, for example, 2 μm or more, preferably 20 μm or more, and is, for example, 200 μm or less, preferably 150 μm or less.

Although the signal electrode 21 stretches along the entire length of the waveguide device 100 in FIG. 1, any length suitable for the use of the waveguide device 100 is adoptable for the signal electrode 21. The waveguide device 100 may be provided with a plurality of signal electrodes 21 aligned in a waveguide direction.

In one embodiment, the conductor layer 2 further includes second ground electrodes 22 in addition to the signal electrode 21. The second ground electrodes 22 are arranged in a direction intersecting (preferably perpendicular to) the longitudinal direction of the signal electrode 21, positioned at a distance from the signal electrode 21. Thus, a clearance (slit) extending in the longitudinal direction of the signal electrode 21 is formed between the signal electrode 21 and the second ground electrodes 22. The width “g” of the clearance (slit) is, for example, 2 μm or more, preferably 5 μm or more, and is, for example, 100 μm or less, preferably 80 μm or less.

In the illustrated example, the conductor layer 2 includes the signal electrode 21 and two second ground electrodes 22a and 22b. The second ground electrode 22a is positioned on a side opposite from the second ground electrode 22b with respect to the signal electrode 21. In the waveguide devices 100 and 101 illustrated in FIGS. 1 to 14, the signal electrode 21 and the second ground electrodes 22a and 22b form a coplanar line which serves as one example of a transmission line. That is, the signal electrode 21 and the second ground electrodes 22 are coplanar electrodes.

In such a coplanar line, when a voltage is applied to the conductor layer 2, an electric field is generated between the signal electrode 21 and the second ground electrodes 22. When the above-mentioned high-frequency electromagnetic wave is input into the waveguide device 100, it may propagate through the resin material substrate 1 while being coupled with the electric field generated between the signal electrode 21 and the second ground electrodes 22.

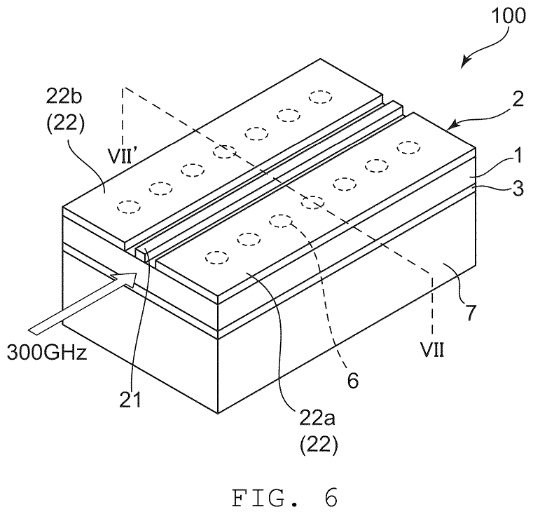

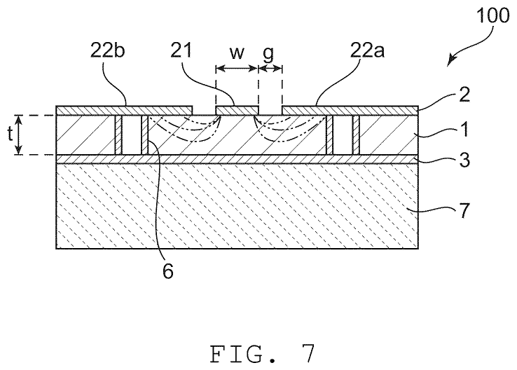

In addition, as illustrated in FIGS. 6 and 7, the second ground electrodes 22 and the first ground electrode 3 may be conducted to each other. When the second ground electrodes 22 and the first ground electrode 3 are conducted to each other, grounding can be strengthened, and hence stray capacitance due to a surrounding line or device can be suppressed.

In the illustrated example, a plurality of via holes are formed in the resin material substrate 1, and vias 6 positioned in the respective via holes short-circuit the first ground electrode 3 and the second ground electrode 22a as well as the first ground electrode 3 and the second ground electrode 22b. There is no particular limitation on the arrangement of the plurality of vias 6 (via holes). In the illustrated example, the plurality of vias 6 (via holes) are aligned in the longitudinal direction of the signal electrode 21. A line of vias 6 short-circuits the first ground electrode 3 and the second ground electrode 22a, while a line of vias 6 short-circuits the first ground electrode 3 and the second ground electrode 22b. These two lines of vias 6 are arranged in a direction intersecting the longitudinal direction of the signal electrode 21, at a distance from each other. Each of the vias 6 is typically a conductive film formed over the entire inner surface of the corresponding via hole. Each of the vias 6 includes a conductive material, which typically includes the same metal (described later) as that of the conductor layer 2. The entire interior of each via hole may be filled with the conductive material. When the vias are each formed from a metal film, the inside of each hole may be filled with the conductive material. The conductive material may be the same metal as that of each via, or may be another material such as a conductive paste.

### A-2. Overall Configuration of Waveguide Device 101

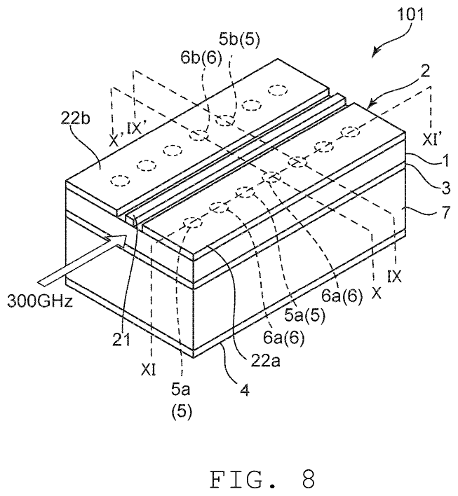

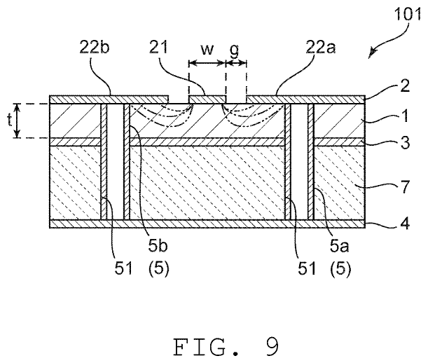

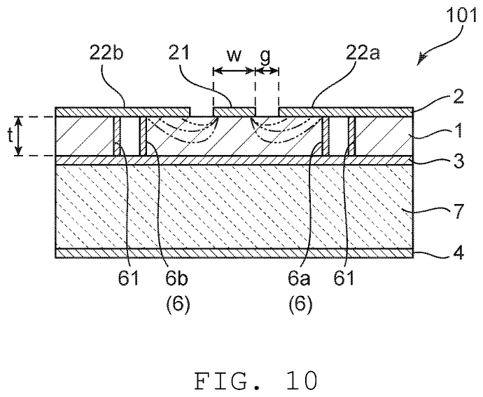

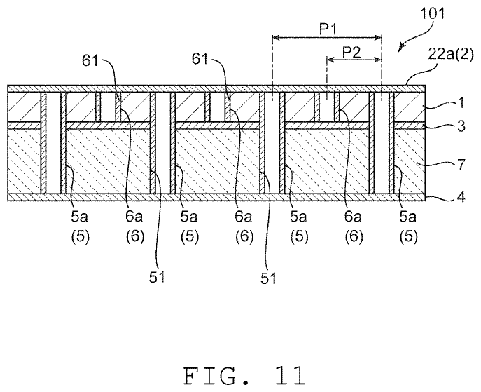

FIG. 8 is a schematic perspective view of a waveguide device 101 according to another embodiment of the present invention, FIG. 9 is a cross-sectional view of the waveguide device 101 taken along the line IX-IX′ of FIG. 8, FIG. 10 is a cross-sectional view of the waveguide device 101 taken along the line X-X′ of FIG. 8, and FIG. 11 is a cross-sectional view of the waveguide device 101 taken along the line XI-XI′ of FIG. 8.

A waveguide device 101 of the illustrated example includes, in addition to the resin material substrate 1 described above, the conductor layer 2 described above, the first ground electrode 3 described above, and the support substrate 7 described above, a third ground electrode 4 as well. Although not shown, the waveguide device 101 may also include the joining portion 8 described above. The third ground electrode 4 is positioned on a side opposite from the first ground electrode 3 with respect to the support substrate 7. In the illustrated example, the third ground electrode 4 is formed on the surface of the support substrate 7 on the side opposite the first ground electrode 3, and is in direct contact with the support substrate 7. With such configuration, the first ground electrode 3 is arranged between the resin material substrate 1 and the support substrate 7, and the third ground electrode 4 is arranged on the side opposite the first ground electrode 3 with respect to the support substrate 7, and hence an electromagnetic wave can be further suppressed from leaking to the support substrate 7.

In one embodiment, the waveguide device 101 may further include a first via 5 and a second via 6. As illustrated in FIG. 9, the first via 5 electrically connects the second ground electrodes 22 and the third ground electrode 4 to each other, and is electrically connected to the first ground electrode 3. The waveguide device 101 includes the plurality of first vias 5 described above (see FIG. 8). As illustrated in FIG. 10, the second via 6 electrically connects the first ground electrode 3 and the second ground electrodes 22 to each other. The second via 6 is arranged between two first vias 5 adjacent to each other out of the plurality of first vias 5 (see FIG. 8). With such configuration, the first vias 5 electrically connects the first ground electrode 3, the second ground electrode 22, and the third ground electrode 4 to each other. Accordingly, this arrangement can strengthen grounding, and hence stray capacitance due to a surrounding line or device can be more stably suppressed. In addition, an excellent heat-dissipating function can be imparted to the support substrate 7, and transmission in a high-order mode can be suppressed. In addition, accuracy can be secured with ease for relative positions of a portion of the first via 5 that is positioned between the first ground electrode 3 and the second ground electrode 22 and a portion of the first via 5 that is positioned between the first ground electrode 3 and the third ground electrode 4. And occurrence of a ripple can accordingly be suppressed.

Further, the second via 6 is arranged between two first vias 5 adjacent to each other, and hence a pitch between each of the first vias 5 and the second via 6 in the resin material substrate 1 can be made smaller than a pitch between the first vias 5 in the support substrate 7. Accordingly, even when the resin material substrate 1 is thinned, the strength of the resin material substrate 7 can be sufficiently secured.

### A-2-1. First Vias 5

As illustrated in FIG. 9, in the waveguide device 101, the first vias 5 are arranged on both sides of the signal electrode 21 in a direction intersecting (preferably perpendicular to) the longitudinal direction of the signal electrode 21. Hereinafter, the first via that electrically connects the second ground electrode 22a and the third ground electrode 4 to each other is referred to as “first via 5a.” And the first via that electrically connects the second ground electrode 22b and the third ground electrode 4 to each other is referred to as “first via 5b.”

The first via 5a is brought into contact with the second ground electrode 22a and the third ground electrode 4, and continuously extends between the second ground electrode 22a and the third ground electrode 4. The first via 5b is brought into contact with the second ground electrode 22b and the third ground electrode 4, and continuously extends between the second ground electrode 22b and the third ground electrode 4. Each of the first vias 5a and 5b penetrates through the first ground electrode 3, and is in contact with the first ground electrode 3. The waveguide device 101 may include only one of the first via 5a or 5b.

The first vias 5 are each typically a conductive film. Each of the first vias 5 includes a conductive material, and typically includes the same metal (described later) as that of the conductor layer 2. The shape of each first via 5 corresponds to the shape of a first via hole 51 in which the via is arranged. In other words, the waveguide device 101 includes a plurality of the first via holes 51 in correspondence with the plurality of first vias 5. Each of the first via holes 51 penetrates through the resin material substrate 1, the first ground electrode 3, and the support substrate 7. Each of the first via holes 51 typically has a circular shape when viewed from above the resin material substrate 1. When each of the first via holes 51 has a circular shape, the inner diameter of each first via hole 51 may be, for example, 10 μm or more, preferably 20 μm or more, and may be, for example, 200 μm or less, preferably 100 μm or less, and more preferably 80 μm or less.

In FIG. 9, each of the first via holes 51 has a circular shape when viewed from above the resin material substrate 1, and linearly penetrates through the resin material substrate 1, the first ground electrode 3, and the support substrate 7 in the thickness direction of the resin material substrate 1. In the case where the first via holes are circular and linear, each of the first vias 5 may have a columnar shape or a cylindrical shape extending in the thickness direction of the resin material substrate 1. In this case, the range of the outer diameter of each first via 5 may correspond to the range of the inner diameter of each first via hole 51 described above.

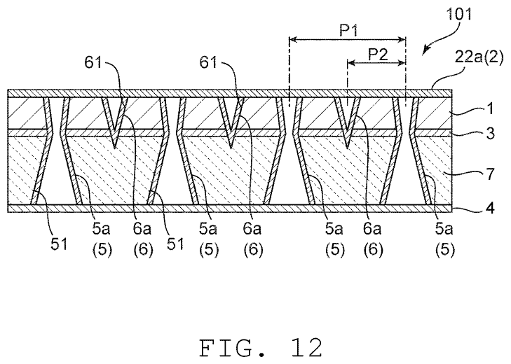

As illustrated in FIG. 12, each first via hole 51 may have a circular shape when viewed from above the resin material substrate 1, and have such a tapered shape such that its diameter becomes smaller as its distance from the first ground electrode 3 becomes shorter. In addition, each first via hole 51 may have a circular shape when viewed from above the resin material substrate 1, and may have a tapered shape such that its diameter becomes larger as its distance from the ground electrode 3 becomes shorter, though the tapered shape is not shown.

When each first via hole 51 has a tapered shape, the following features can be imparted to each of the via holes 51: it becomes easier to form the conductive film in the first via 51; and it becomes easier to secure the strength of the support substrate 7. In addition, the first vias 51 may be formed so that the conductive material may be embedded in each of the first via holes 51.

When each first via hole 51 has a circular shape and a tapered shape, each first via 5 preferably has such an hourglass shape that its portion in contact with the first ground electrode 3 has a small diameter, and its diameter becomes larger as its distance from the first ground electrode 3 becomes longer. In other words, each first via 5 preferably has a shape obtained by linking the apices of two cones to each other. In this case, the maximum outer diameter of each first via 5 falls within the above-mentioned ranges. In one embodiment, the outer diameter of one end portion of each first via 5 in contact with the second ground electrode 22 is smaller than the outer diameter of the other end portion of the first via 5 in contact with the third ground electrode 4. In each first via 5, a taper angle on the conductor layer 2 side with respect to the first ground electrode 3 is smaller than a taper angle on the third ground electrode 4 side with respect to the first ground electrode 3.

In the illustrated example, the second ground electrode 22 and the third ground electrode 4 are formed so as to close the first via holes 51. However, the configurations of the second ground electrode 22 and the third ground electrode 4 are not limited thereto. Each of the second ground electrode 22 and the third ground electrode 4 only needs to be conducted to the first vias 5, and may be opened without closing the first via holes 51.

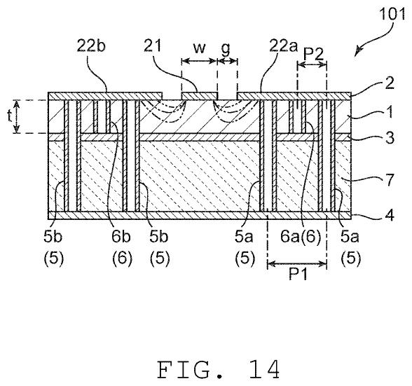

In addition, in the waveguide device 101 illustrated in each of FIGS. 8 to 12, a plurality of first vias 5a are arranged at a distance from each other in the longitudinal direction of the signal electrode 21. The direction in which the plurality of first vias 5 are arranged is not limited to the longitudinal direction of the signal electrode 21. As illustrated in FIG. 14, the plurality of first vias 5a may be arranged at a distance from each other in a direction intersecting (preferably perpendicular to) the longitudinal direction of the signal electrode 21. In addition, the waveguide device 101 may include, in the direction intersecting (perpendicular to) the longitudinal direction of the signal electrode 21, a plurality of rows of the first vias 5a arranged in the longitudinal direction of the signal electrode 21.

As illustrated in FIG. 12, a pitch P1 between the plurality of first vias 5a (distance between the centers of the first vias 5a adjacent to each other) may be, for example, 40 μm or more, preferably 60 μm or more, and may be, for example, 600 μm or less, preferably 400 μm or less, more preferably 200 μm or less.

The waveguide device 101 may include a plurality of first vias 5b as is the case for the first vias 5a.

### A-2-2. Second Vias 6

As illustrated in FIG. 8, in the waveguide device 101, the second vias 6 are arranged on both sides of the signal electrode 21 in a direction intersecting (preferably perpendicular to) the longitudinal direction of the signal electrode 21. Hereinafter, the second via 6 that electrically connects the second ground electrode 22a and the first ground electrode 3 to each other may be referred to as “second via 6a”, and the second via 6 that electrically connects the second ground electrode 22b and the first ground electrode 3 to each other may be referred to as “second via 6b.” The second via 6a may be in contact with the second ground electrode 22a and the first ground electrode 3, and may be out of contact with the third ground electrode 4. The second via 6b may be in contact with the second ground electrode 22b and the first ground electrode 3, and may be out of contact with the third ground electrode 4. The waveguide device 101 may include only one of the second vias 6a and 6b.

Each of the second vias 6 is typically a conductive film. Each second via 6 includes a conductive material, and typically includes the same metal (described later) as that used in each of the first vias 5. The shape of each second via 6 corresponds to the shape of a second via hole 61 in which the via is arranged. In other words, the waveguide device 101 includes the second via holes 61 corresponding to the second vias 6.

As illustrated in FIG. 10, each second via hole 61 penetrates through at least the resin material substrate 1, and does not penetrate through the support substrate 7. Each of the second via holes 61 typically has a circular shape when viewed from above the resin material substrate 1. When each of the second via holes has a circular shape, the ranges of the inner diameter of each second via hole 61 corresponds to, for example, the ranges of the inner diameter of each first via hole 51 described above.

In the illustrated example, each second via hole 61 linearly penetrates through the resin material substrate 1 in the thickness direction of the resin material substrate 1, and does not penetrate through the first ground electrode 3. In the case where the second via holes 61 are circular and linear, each of second vias 6 has a columnar shape or a cylindrical shape extending in the thickness direction of the resin material substrate 1. In this case, the ranges of the outer diameter of each second via 6 correspond to the ranges of the inner diameter of each of the second via holes 61 described above.

As illustrated in FIG. 12, each second via hole 61 has a conical shape that tapers as its distance from the conductor layer 2 becomes longer. In the illustrated example, each second via hole 61 penetrates through the resin material substrate 1 and the first ground electrode 3, and the tip of each second via hole reaches the support substrate 7. In the case where the second via holes 61 have conical shapes, the second vias 6 preferably have the same conical shapes as those of the second via holes 61. In this case, the maximum outer diameter of each of the second vias 6 falls within the ranges of the inner diameter of each second via hole 61 described above. In addition, the apex portions of the second vias 6 (end portions of the second vias 6 on the side opposite from the conductor layer 2) may reach the support substrate 7.

In the illustrated example, the second ground electrodes 22a are formed so as to close the second via holes 61. However, the configurations of the second ground electrodes 22a are not limited thereto. Each second ground electrode 22a only needs to be conducted to the second vias 6, and may be opened without closing the second via holes 61.

As illustrated in each of FIGS. 11 to 14, the second vias 6 are each arranged between two first vias 5 adjacent to each other out of the plurality of first vias 5 arranged in a predetermined direction. The second vias 6 are each typically positioned at the center of an interval between two first vias 5 adjacent to each other.

The waveguide device 101 of the illustrated example includes the plurality of second vias 6 (the plurality of second vias 6a and the plurality of second vias 6b). In each of the illustrated examples shown in FIGS. 8 to 13, each of second vias 6 is arranged between two first vias 5 adjacent to each other in the longitudinal direction of the signal electrode 21. The second vias 6 illustrated in FIG. 14 are each arranged between two first vias 5 adjacent to each other in a direction intersecting (preferably perpendicular to) the longitudinal direction of the signal electrode 21.

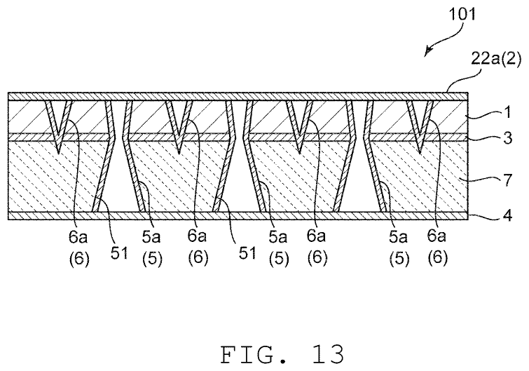

In addition, each second via 6 may be arranged at any appropriate position as long as the via is present between two first vias 5 adjacent to each other. The second vias 6 may each be arranged every “n” first vias 5 in the direction in which the plurality of first vias are arranged. “n” represents, for example, 1 or more and 5 or less, preferably 1 or 2. It is more preferred that the first vias 5 and the second vias 6 be alternately arranged. In addition, all of the plurality of second vias 6 may each be arranged between two first vias 5 adjacent to each other as illustrated in each of FIGS. 11 and 12, or the second via 6 that is not arranged between the first vias 5 may be present as illustrated in FIG. 13 as long as at least one of the second vias 6 is arranged between two first vias 5 adjacent to each other.

As illustrated in FIG. 12, a pitch P2 between the first via 5 and the second via 6 adjacent to each other (measured as the distance between the centers of the first via 5a and the second via 6a adjacent to each other) may be approximately half of the pitch P1 (measured as the distance between the centers of the first vias 5a adjacent to each other), and the pitch P2 may be, for example, 25 μm or more, preferably 60 μm or more, and may be, for example, 600 μm or less, preferably 400 μm or less, more preferably 200 μm or less.

When each second via 6 is arranged between two first vias 5 adjacent to each other as described above, the pitch P2 between the first via 5 and the second via 6 in the resin material substrate 1 can be made smaller than the pitch P1 between the first vias 5 in the support substrate 7. Accordingly, even when the resin material substrate 1 is thinned, the strength of the resin material substrate 1 can be sufficiently secured.

### A-2-3. Modification Example of Waveguide Device 101

Although not shown, the waveguide device 101 may include, instead of the first via 5, a third via which electrically connects the first ground electrode 3 and the third ground electrode 4. That is, the waveguide device 101 may include, as separate vias, the second via 6 which connects the first ground electrode 3 and the second ground electrodes 22 to each other and a third via which connects the first ground electrode 3 and the third ground electrode 4. With this configuration, however, accuracy may decrease in the relative positions of the second via 6 which connects the first ground electrode 3 and the second ground electrode 22 and the third via which connects the first ground electrode 3 and the third ground electrode 4. In this case, an increase in misalignment between the second via 6 and the third via may cause a ripple in frequency characteristics. It is accordingly more preferred for the waveguide device 101 to include the first via 5 in order to suppress ripples. In addition, a waveguide device 101 that includes the first via 5 can be manufactured smoothly compared to a waveguide device 101 that includes the second via 6 and the third via.

In addition, although not shown, the waveguide device 101 may exclude the second via 6 while including the first vias 5. However, as illustrated in FIG. 12, when each first via hole 51 has such a tapered shape that its diameter becomes larger as its distance from the first ground electrode 3 becomes longer, and the thickness of the support substrate 7 is larger than that of the resin material substrate 1, the outer diameter of one end portion of each of the first vias 5 in contact with the corresponding second ground electrode 22 becomes smaller than the outer diameter of the other end portion of the first via 5 in contact with the third ground electrode 4 in some cases. In such cases, when a pitch between the plurality of first vias 5 is narrowed like the above-mentioned pitch P2 without the arrangement of the second via 6, the other end portions of the first vias 5 may interfere with each other. Accordingly, it is preferred that the waveguide device 101 includes the first vias 5 and the second vias 6, and each of the second vias 6 is arranged between two first vias 5 adjacent to each other because the interference between the first vias 5 can be suppressed.

### A-3. Overall Configuration of Waveguide Device 102

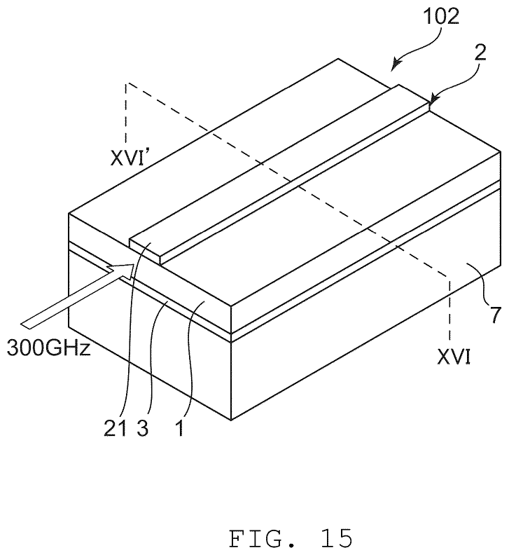

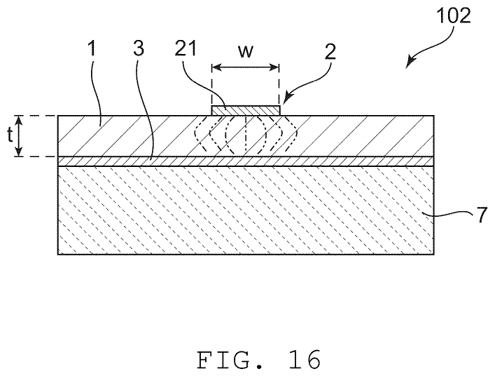

FIG. 15 is a schematic perspective view of a waveguide device 102 according to still another embodiment of the present invention, and FIG. 16 is a cross-sectional view of the waveguide device 102 taken along the line XVI-XVI′ of FIG. 15.

In the waveguide device 102, the signal electrode 21 forms a microstrip line serving as an example of the transmission line together with the first ground electrode 3. That is, the signal electrode 21 and the first ground electrode 3 function as microstrip-type electrodes. Although not shown, the waveguide device 102 may include the joining portion described above.

In the case where the signal electrode 21 is a microstrip-type electrode, the width “w” of the signal electrode 21 may be, for example, 100 μm or more, preferably 300 μm or more, and may be, for example, 800 μm or less, preferably 500 μm or less.

When the signal electrode 21 and the first ground electrode 3 are microstrip-type electrodes, the above-mentioned high-frequency electromagnetic wave propagates in the resin material substrate 1 while being coupled with an electric field generated between the signal electrode 21 and the first ground electrode 3.

### A-4. Overall Configuration of Waveguide Device 103

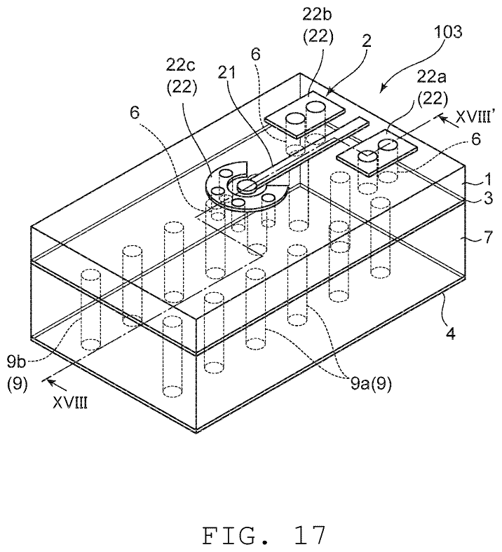

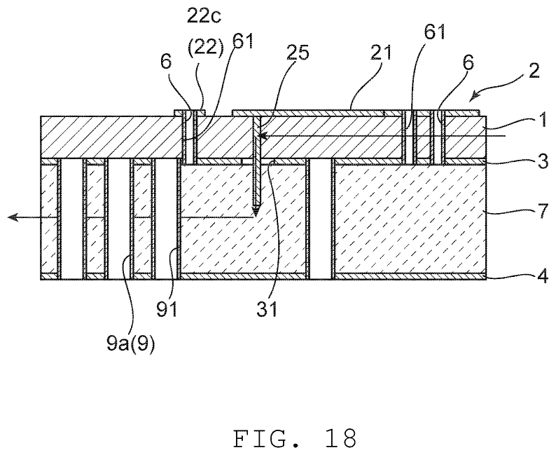

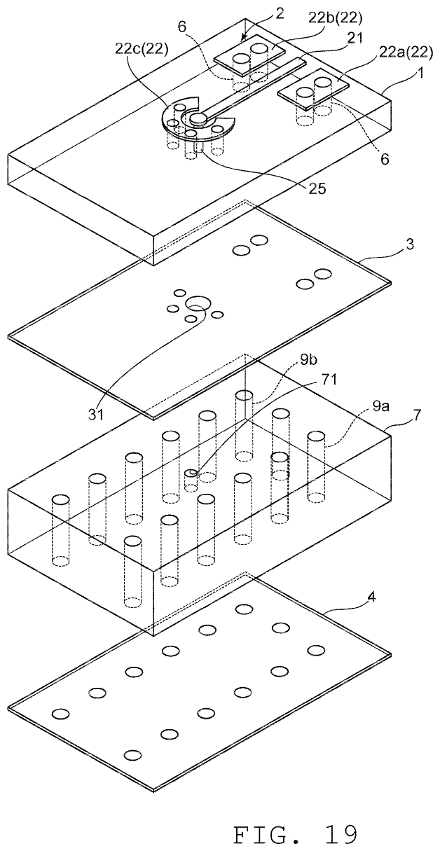

FIG. 17 is a schematic perspective view of a waveguide device 103 according to yet still another embodiment of the present invention, FIG. 18 is a cross-sectional view of the waveguide device 103 taken along the line XVIII-XVIII′ of FIG. 17, and FIG. 19 is an exploded perspective view of the waveguide device 103 of FIG. 17.

A waveguide device 103 of the illustrated example further includes the plurality of through-substrate vias 9 in addition to the above-mentioned resin material substrate 1, the above-mentioned conductor layer 2, the above-mentioned first ground electrode 3, the above-mentioned support substrate 7, and the above-mentioned third ground electrode 4. The waveguide device 103 may also include the above-mentioned joining portion, though the portion is not shown. Each of the plurality of through-substrate vias 9 electrically connects the first ground electrode 3 and the third ground electrode 4 to each other. The first ground electrode 3, the third ground electrode 4, and the plurality of through-substrate vias 9 form a substrate-integrated waveguide (hereinafter referred to as “SIW”) that can propagate an electromagnetic wave. Thus, the SIW can be arranged in the support substrate 7, and hence the support substrate 7 can be effectively utilized as a waveguide.

The signal electrode 21 of the illustrated example forms a microstrip line serving as an example of the transmission line together with the first ground electrode 3.

In one embodiment, the second ground electrodes 22 further include a second ground electrode 22c, in addition to the second ground electrodes 22a and 22b described above. In this embodiment, one end portion of the signal electrode 21 is positioned between the second ground electrodes 22a and 22b arranged at a distance from each other. The second ground electrodes 22a and 22b may be electrically connectable to an external device (not shown). The second ground electrode 22c is arranged at a predetermined distance from the other end portion of the signal electrode 21. The second ground electrode 22c has a substantially C-shape when viewed from above, and surrounds the other end portion of the signal electrode 21. The conductor layer 2 may omit the second ground electrode 22c. In addition, the signal electrode 21 may form coplanar-type electrodes serving as an example of the transmission line together with the second ground electrodes 22a and 22b.

In addition, the waveguide device 103 may further include the above-mentioned vias 6. Thus, this configuration can strengthen grounding, and hence stray capacitance due to a surrounding line or device can be suppressed. In the illustrated example, each of the second ground electrodes 22a, 22b, and 22c is electrically connected to the first ground electrode 3 by the plurality of vias 6.

The plurality of through-substrate vias 9 penetrate through the support substrate 7 in the thickness direction of the support substrate 7, and are periodically arranged in the support substrate 7. The plurality of through-substrate vias 9 typically include a first via row 9a and a second via row 9b. Each of the first via row 9a and the second via row 9b is formed of a plurality of through-substrate vias 9 arranged at a distance from each other in a predetermined direction. The second via row 9b is positioned away from the first via row 9a in a direction perpendicular to the direction in which the first via row 9a extends. In one embodiment, an area in the support substrate 7 surrounded by the first ground electrode 3, the third ground electrode 4, the first via row 9a, and the second via row 9b functions as the SIW.

As illustrated in FIG. 18, each of the through-substrate vias 9 includes a conductor material, and typically includes the same metal (described later) as that of the conductor layer 2. The through-substrate vias 9 are each arranged in a substrate via hole 91. That is, the waveguide device 103 has a plurality of the substrate via holes 91 in correspondence to the plurality of through-substrate vias 9. In the illustrated example, the substrate via holes 91 penetrate through the first ground electrode 3, the support substrate 7, and the third ground electrode 4 collectively. Each of through-substrate vias 9 is typically a conductive film formed over the entire inner surface of the substrate via hole 91. The substrate via holes 91 may penetrate through only the support substrate 7 without penetrating through the first ground electrode 3 and the third ground electrode 4. In this case, the through-substrate vias 9 are caused to fill the substrate via holes 91 in such a manner as to be brought into contact with the first ground electrode 3 and the third ground electrode. In addition, when the through-substrate vias 9 for conducting the first ground electrode 3 and the third ground electrode 4 to each other are each formed from a conductor film, the inside thereof may be filled with a material such as a resin.

In the waveguide device 103, a transmission line formed by the signal electrode 21 and the SIW may be independent of each other, or may be coupled to each other so as to enable an electromagnetic wave to be propagated. In one embodiment, a transmission line (typically, microstrip-type transmission line) formed by the signal electrode 21 and the SIW are coupled to each other by a conductor pin 25. Thus, the propagation mode of the electromagnetic wave can be converted between a transmission line mode and a waveguide mode. For example, an electromagnetic wave (signal) in the transmission line mode propagating through the resin material substrate 1 can be converted via the conductor pin 25 into an electromagnetic wave in the waveguide mode propagating through the support substrate 7. The support substrate 7 may also function as an antenna for spatially radiating the electromagnetic wave propagating in the waveguide mode in the in-plane direction of the support substrate 7.

The conductor pin 25 penetrates through the resin material substrate 1 from the signal electrode 21 to reach the SIW in the support substrate 7. The conductor pin 25 may serve as a propagation medium for an electromagnetic wave. The conductor pin 25 includes a conductor material, and typically includes the same metal (described later) as that of each of the conductor layer 2. In the illustrated example, the conductor pin 25 extends in the thickness direction of the resin material substrate 1. The conductor pin 25 may have a pillar shape such as a columnar shape, or may have a tubular shape (hollow shape) such as a cylindrical shape. The base end portion of the conductor pin 25 is connected to an end portion of the signal electrode 21. The free end portion of the conductor pin 25 is inserted into a recess 71 formed in the support substrate 7 (see FIG. 19). The recess 71 is positioned between the first via row 9a and the second via row 9b. The portion of the conductor pin 25 between the base end portion and the free end portion is inserted into an opening 31 in the first ground electrode 3.

The conductor pin 25 is preferably insulated from the first ground electrode 3. In one embodiment, as illustrated in FIG. 18, the opening 31 forms an air layer around the conductor pin 25. The opening 31 is larger than the contour of the conductor pin 25 with the entire periphery of the opening 31 spaced away from the conductor pin 25. Thus, this configuration may allow the conductor pin 25 to be insulated from the first ground electrode 3, and by extension, the signal electrode 21 and the first ground electrode 3 can be stably insulated. In addition, substrate resonance due to the leakage of an electric field to the support substrate 7 can be still further suppressed. Further, the influence of the dielectric loss can be suppressed as compared to a structure in which the air layer is filled with a resin.

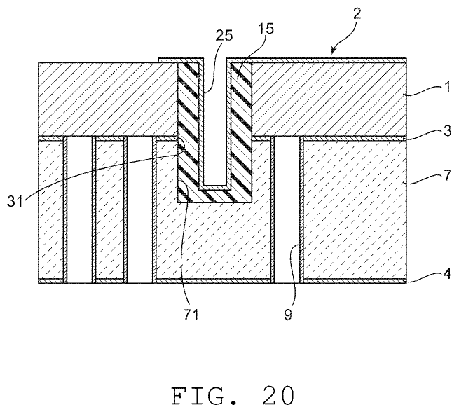

As illustrated in FIG. 20, the periphery of the conductor pin 25 may be covered with an insulating material 15. Also in this case, the conductor pin 25 can be insulated from the first ground electrode. Examples of the insulating material include a resin and SiO₂.

### A-5. Overall Configuration of Waveguide Device 104

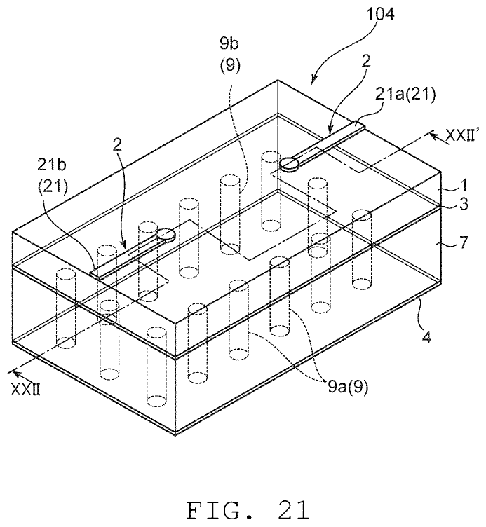

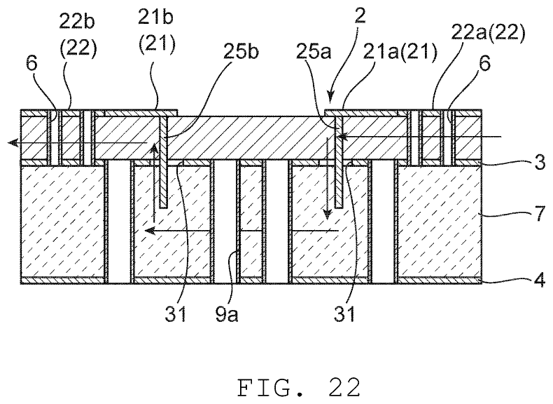

FIG. 21 is a schematic perspective view of a waveguide device 104 according to still another embodiment of the present invention, and FIG. 22 is a cross-sectional view of the waveguide device 104 taken along the line XXII-XXII′ of FIG. 21. In FIG. 21, the second ground electrode 22 and the vias are omitted for convenience.

A waveguide device 104 includes a plurality of the signal electrodes 21 positioned away from each other. Accordingly, the waveguide device 104 includes a plurality of transmission lines corresponding to the signal electrodes 21. In the illustrated example, the waveguide device 104 includes: the conductor layer 2 including a first signal electrode 21a and a second signal electrode 21b; a first conductor pin 25a; and a second conductor pin 25b. The first signal electrode 21a forms a first transmission line together with the first ground electrode 3, and the second signal electrode 21b forms a second transmission line together with the first ground electrode 3. The first conductor pin 25a couples the SIW, which is formed by the first ground electrode 3, the third ground electrode 4, and the plurality of through-substrate vias 9, and the first transmission line to each other. The second conductor pin 25b couples the SIW, which is formed by the first ground electrode 3, the third ground electrode 4, and the plurality of through-substrate vias 9, and the second transmission line to each other.

Thus, in one embodiment, an electromagnetic wave (signal) in the transmission line mode propagating through the resin material substrate 1 can be converted into the SIW mode via the first conductor pin 25a, then propagated through the support substrate 7 in the SIW mode, and then converted via the second conductor pin 25b again into the transmission line mode propagating through the resin material substrate 1. In this embodiment, the electromagnetic wave that has propagated through the resin material substrate 1 may be emitted from an antenna device arranged on the resin material substrate 1.

### A-6. Overall Configuration of Waveguide Device 105

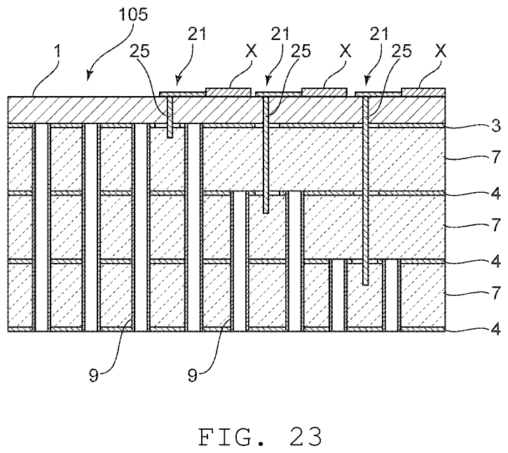

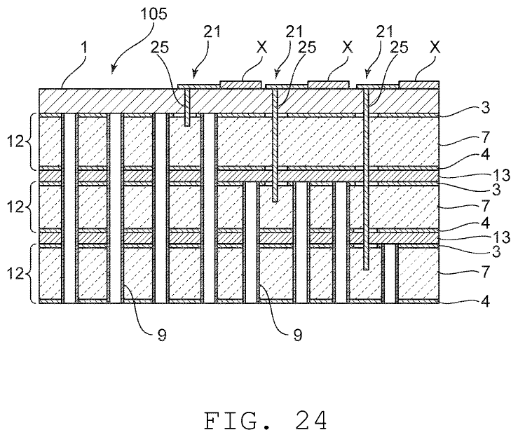

FIG. 23 is a schematic cross-sectional view of a waveguide device 105 according to yet still another embodiment of the present invention, and FIG. 24 is a schematic cross-sectional view for illustrating a modification example of the waveguide device 105 of FIG. 23.

The above-mentioned waveguide devices 100 to 104 each include one support substrate 7, but the number of the support substrates 7 is not particularly limited. In a waveguide device 105, a plurality of support substrates 7 are arranged at a distance from each other in the thickness direction of the resin material substrate 1, and a substrate-integrated waveguide (SIW) is arranged in each of the plurality of support substrates 7. With such configuration, antenna portions for radiating electromagnetic waves in the SIW mode can be arrayed in the thickness direction. Accordingly, such waveguide device can be used as a phased array antenna in wireless communications. In the case of integrating a plurality of substrates that transmit signals (electromagnetic waves), heat generation of the waveguide device may become a concern. In the embodiment described above, however, heat is smoothly dissipated from the waveguide device 105 because the resin material substrate 1 and the support substrates 7 are directly joined to each other, and through-substrate vias 9 which penetrate through the support substrates 7 are connected to the ground electrodes.

As illustrated in FIG. 23, in the waveguide device 105, the third ground electrode 4 is arranged between two support substrates 7 adjacent to each other out of the plurality of support substrates 7. Thus, the SIW to be arranged in each of the support substrates 7 is formed by the metal layers arranged on both sides of the support substrate 7 (i.e., the first ground electrode 3 and the third ground electrode 4, or two third ground electrodes 4) and the plurality of through-substrate vias 9 that penetrate through the support substrate 7.

As illustrated in FIG. 24, in the waveguide device 105, a plurality of waveguide units 12 each including a SIW may be arranged at a distance from each other in the thickness direction of the resin material substrate 1. Each of the plurality of waveguide units 12 includes the first ground electrode 3, the support substrate 7, the third ground electrode 4, and the plurality of through-substrate vias 9.

A spacer substrate 13 may be arranged between two support substrates 7 adjacent to each other out of the plurality of support substrates 7. In one embodiment, the spacer substrate 13 may be arranged between two waveguide units 12 adjacent to each other. Through the arrangement of the spacer substrate 13, a distance between antenna portions in the plurality of support substrates 7 can be adjusted. In particular, when the distance between the plurality of antenna portions is adjusted to A/2, the radiation angle of an electromagnetic wave can be sufficiently scanned. As a material for the spacer substrate 13, there is typically given the same resin material (described later) as that for the resin material substrate 1.

In addition, the waveguide device 105 including the plurality of SIWs preferably includes the signal electrodes 21 and the conductor pins 25 in the same numbers as that of the SIWs. The respective conductor pins 25 couple transmission paths formed by the respective signal electrodes 21 to the corresponding SIWs. The conductor pin 25 penetrates through the resin material substrate 1 from the corresponding signal electrode 21, is inserted into the opening 31 of the first ground electrode 3, and as required, further penetrates through the support substrate 7, the third ground electrode 4, and the spacer substrate 13, to reach the target support substrate 7. With such configuration, while the waveguide device 105 can be relatively easily produced, signals (electromagnetic waves) from external signal sources X arranged on the resin material substrate 1 can be easily propagated to the SIW of each support substrate 7.

As used herein, the term “waveguide device” encompasses both of a wafer having formed thereon at least one of the waveguide devices 100 to 105 (waveguide device wafer) and a chip obtained by cutting the waveguide device wafer.

Specific configurations of the resin material substrate 1, the conductor layer 2, the first ground electrode 3, the third ground electrode 4, the support substrate 7, and the joining portion 8 are described below.

### B. Resin Material Substrate 1

As illustrated in FIG. 1, the resin material substrate 1 includes an upper surface on which the conductor layer 2 is provided and a lower surface positioned in a composite substrate. The resin material substrate 1 has a thickness which satisfies, for example, Formula (1):

$$t < \frac{λ}{a \sqrt{ε}} \qquad ( 1 )$$

where “t” represents the thickness of the resin material substrate 1, λ represents a wavelength of the electromagnetic wave guided by the waveguide device, c represents a relative dielectric constant of the resin material substrate at 150 GHz, and “a” represents a numerical value of 3 or more.

When the thickness of the resin material substrate 1 satisfies Formula (1), even in a case where the waveguide device guides the high-frequency electromagnetic wave described above, inducement of a slab mode and the occurrence of substrate resonance can be suppressed. Accordingly, the waveguide device described above can satisfactorily be reduced in propagation loss even in the case of guiding the high-frequency electromagnetic wave described above.

Downsizing is being advanced in waveguide devices that are under development and, in light of a prospect of circuit integration in the future, accompanying downsizing is expected to be demanded of a waveguide device (line structure). In the waveguide devices described above, the thickness of the resin material substrate 1 that satisfies Formula (1) is thin, and can accordingly meet the demand for downsizing at the same time as reducing a propagation loss.

In one embodiment, in Formula (1), “a” represents a numerical value of 6 or more.

When the thickness of the resin material substrate 1 satisfies Formula (1) where “a” represents a numerical value of 6 or more, a reduction in propagation loss in the case of guiding the above-mentioned high-frequency electromagnetic wave can be stably achieved.

The relative dielectric constant ε of the resin material substrate 1 at 150 GHz may typically be 1.5 or more, and may typically be 4.0 or less, preferably 3.5 or less, more preferably 3.0 or less.

The dielectric loss tangent (dielectric loss) tan δ of the resin material substrate 1 at 150 GHz is typically 0.01 or less, preferably 0.005 or less, more preferably 0.002 or less. When the dielectric loss tangent is within this range, a propagation loss in the waveguide can be reduced. A smaller dielectric loss tangent is preferred. The dielectric loss tangent may be, for example, 0.0001 or more.

When the relative dielectric constant ε and the dielectric loss tangent (dielectric loss) tan δ of the resin material substrate fall within the above-mentioned ranges, a reduction in propagation loss in the case of guiding the above-mentioned high-frequency electromagnetic wave (in particular, an electromagnetic wave of 150 GHz or more) can be more stably achieved. The relative dielectric constant ε and the dielectric loss tangent (dielectric loss) tan δ may be measured by terahertz time domain spectroscopy. In addition, herein, when the measurement frequency is not mentioned with regard to the relative dielectric constant and the dielectric loss tangent, the relative dielectric constant and the dielectric loss tangent at 150 GHz are meant.

The thickness of the resin material substrate 1 that satisfies Formula (1) is specifically 1 μm or more, preferably 2 μm or more, more preferably 10 μm or more, still more preferably 20 μm or more. The thickness of the resin material substrate 1 is specifically, for example, 1,700 μm or less, preferably 500 μm or less, more preferably 200 μm or less, still more preferably 100 μm or less. From the viewpoint of downsizing through a reduction in size of an electrode, the thickness of the resin material substrate 1 may preferably be 80 μm or less, more preferably 60 μm or less. In addition, when the frequency of the electromagnetic wave to be propagated through the waveguide device is 30 GHz or more and 5 THz or less, the thickness of the resin material substrate 1 may preferably be 10 μm or more. In order to secure strength, the thickness of the resin material substrate 1 may preferably be 30 μm or more, more preferably 40 μm or more.

When the thickness of the resin material substrate 1 is smaller than the above-mentioned lower limits, the thickness and width of an electrode included in the waveguide device are reduced to about several micrometers, and hence the propagation loss is increased by the influence of a skin effect, and besides, a tolerance in line performance due to manufacturing variation is significantly reduced.

When the thickness of the resin material substrate 1 is equal to or smaller than the above-mentioned upper limits, the inducement of a slab mode and the occurrence of substrate resonance are suppressed, and hence a waveguide device having a small propagation loss over a wide frequency range (i.e., a broadband waveguide device) can be achieved.

The resin material substrate 1 is formed of a resin material. As the resin material, any appropriate material is usable as long as the effects according to the embodiments of the present invention are obtained. Typical examples of such material may include fluorine-based resins such as polytetrafuluoroethylene (PTFE); hydrocarbon-based resins such as cycloolefin (COP) and a cyclic olefin copolymer (COC); liquid crystal-based resins such as a liquid crystal polymer (LCP); and polyimide-based resins such as modified polyimide.

The resistivity of the resin material substrate 1 is, for example, 107 kΩ·cm or more, preferably 108 kΩ·cm or more, more preferably 109 kΩ·cm or more, still more preferably 10¹⁰ kΩ·cm or more. When the resistivity falls within these ranges, an electromagnetic wave can propagate in the material with a low loss without influencing electronic conduction. This phenomenon is not clear in detail, but it may be presumed that, when the resistivity is small, the electromagnetic wave couples with an electron, and hence the energy of the electromagnetic wave is consumed by electronic conduction, resulting in a loss. From this viewpoint, the resistivity is preferably as large as possible. The resistivity may be, for example, 10¹⁶ kΩ·cm or less.

A thermal expansion coefficient (linear expansion coefficient) of the resin material substrate 1 is not particularly limited. An upper limit value of the thermal expansion coefficient (linear expansion coefficient) of the resin material substrate 1 is, for example, 80 ppm/K, preferably 70 ppm/K. A lower limit value of the thermal expansion coefficient (linear expansion coefficient) of the resin material substrate 1 is, for example, 10 ppm/K, preferably 12 ppm/K. When the thermal expansion coefficient falls within this range, thermal deformation (typically, warpage) of the substrate can be suppressed satisfactorily. The thermal expansion coefficient may be measured in conformity with the JIS standard R1618.

With such resin material substrate 1, it receives surface treatment such as surface roughening treatment if necessary.

### C. Conductor Layer 2

In one embodiment, the conductor layer 2 is formed on the front surface of the resin material substrate 1 (one surface in its thickness direction), and is in direct contact with the resin material substrate 1.

The conductor layer 2 is typically formed of a metal. Examples of the metal include chromium (Cr), nickel (Ni), copper (Cu), gold (Au), silver (Ag), palladium (Pd), and titanium (Ti). The metals may be used alone or in combination thereof. The conductor layer 2 may be a single layer, or may be formed as a laminate of two or more layers. The conductor layer 2 is formed on the resin material substrate 1 by a publicly-known film forming method (for example, plating, sputtering, vapor deposition, or printing).

The thickness of each of the conductor layer 2 may be, for example, 1 μm or more, preferably 4 μm or more, and may be, for example, 20 μm or less, preferably 10 μm or less.

### D. First Ground Electrode 3 and Third Ground Electrode 4

In one embodiment, the first ground electrode 3 is formed on a surface (preferably a surface treated by surface roughening) of the resin material substrate 1 and/or a surface of the support substrate 7 by, for example, sputtering. The first ground electrode 3 may be formed of a metal similar to the metal of the conductor layer 2. The metal of the first ground electrode 3 may be the same as or differ from the metal of the conductor layer 2. A thickness range of the first ground electrode 3 is the same as the thickness range of the conductor layer 2.

Further, in the case where the first ground electrode 3 functions as the joining portion, the first ground electrode 3 may be formed by: forming metal layers on both of the resin material substrate 1 and the support substrate 7; and directly joining the metal layers to each other. In this case, a joining interface is formed inside the first ground electrode.

As illustrated in FIG. 8, in one embodiment, the third ground electrode 4 is formed on the surface of the support substrate 7 on the side opposite from the first ground electrode 3 by, for example, sputtering or plating. The third ground electrode 4 may be formed of a metal similar to the metal of the conductor layer 2. The metal of the third ground electrode 4 may be the same as or differ from the metal of the conductor layer 2. A thickness range of the third ground electrode 4 is the same as the thickness range of the conductor layer 2. The third ground electrode 4 may not be necessarily formed on the entirety of the surface of the support substrate 7 on the side opposite from the first ground electrode.

### E. Support Substrate 7

The support substrate 7 has an upper surface positioned inside the composite substrate and a lower surface exposed to the outside. The support substrate 7 is arranged in order to improve the strength of the composite substrate, and thus, the thickness of the resin material substrate can be reduced as described above. Any appropriate configuration may be adopted as the support substrate 7. Specific examples of a material for forming the support substrate 7 may include indium phosphide (InP), silicon (Si), glass, SiAlON (Si₃N₄—Al₂O₃), mullite (3Al₂O₃·2SiO₂, 2Al₂O₃·3SiO₂), aluminum nitride (AlN), magnesium oxide (MgO), aluminum oxide (Al₂O₃), spinel (MgAl₂O₄), sapphire, quartz (monocrystalline quartz, amorphous quartz, or the like), crystal, gallium nitride (GaN), silicon carbide (SiC), silicon nitride (Si₃N₄), and gallium oxide (Ga₂O₃).

Thermal conductivity of the support substrate 7 is, for example, 90 W/Km or more, preferably 150 W/Km or more, and is, typically, 500 W/Km or less.

In a case of mounting an active device such as an oscillator or a receiver to the waveguide device, it is preferred to take measures to improve heat dissipation performance of the waveguide device. Accordingly, use of a material having a high thermal conductivity for the support substrate is sometimes desired. In this case, the thermal conductivity of the support substrate is preferably 150 W/Km or more, and the material of the support substrate is preferably selected from silicon (Si), aluminum nitride (AlN), gallium nitride (GaN), silicon carbide (SiC), and silicon nitride (Si₃N₄).

In addition, when a SIW is formed in the support substrate 7, a material having a small dielectric loss tan δ is preferred in order to reduce the loss of the electromagnetic wave to be propagated in the SIW. In this case, the material for the support substrate is preferably selected from monocrystalline quartz, amorphous quartz, spinel, AlN, sapphire, aluminum oxide, SiC, magnesium oxide, or silicon.

Of such materials for the support substrate, silicon is more preferably selected.

The thickness of the support substrate 7 is, for example, λ/4′√ε_{b} or more, preferably λ/2√ε_{b} or more, and for example, 2λ/√ε_{b} or less, preferably 3λ/2′ε_{b} or less, more preferably λ/√ε_{b} or less, where ε_{b} represents the relative dielectric constant of the support substrate 7, and λ represents the wavelength of the electromagnetic wave to be guided by the waveguide device. When the thickness of the support substrate 7 is equal to or larger than the above-mentioned lower limits, an improvement in mechanical strength of the waveguide device can be stably achieved. When the thickness of the support substrate 7 is equal to or smaller than the above-mentioned upper limits, the suppression of slab-mode propagation, the thinning of the waveguide device (retention of the mechanical strength of the waveguide device), and the suppression of substrate resonance can be achieved.

As illustrated in FIGS. 23 and 24, in the case where a plurality of support substrates 7 are arranged at a distance from each other in the thickness direction of the resin material substrate 1, when the waveguide device is used as a phased array antenna, the distance between two support substrates 7 adjacent to each other is desirably about λ/2, which is suited for an antenna pitch. In the case where the thickness of each of the support substrates 7 is less than the distance, an appropriate antenna pitch can be secured by arranging the spacer substrate 13 between two support substrates adjacent to each other.

In a coplanar line, the dielectric loss tangent of the material for forming the support substrate 7 is preferably smaller. In the case of a coplanar line, when the thickness of the resin material substrate is small, the propagating electromagnetic wave may leak to the support substrate 7, and the propagation loss can be suppressed by reducing the dielectric loss tangent. From this viewpoint, the dielectric loss tangent is preferably 0.07 or less.

### F. Joining Portion 8

As illustrated in FIGS. 3 and 4, the joining portion 8 may be one layer, or may be a laminate of two or more layers. The joining portion 8 typically includes an inorganic material. Examples of the joining layer 8 include a SiO₂ layer, an amorphous silicon layer, and a tantalum oxide layer. The joining portion 8 may be a metal film selected from gold (Au), titanium (Ti), platinum (Pt), chromium (Cr), copper (Cu), tin (Sn), or combinations (alloys) thereof. When the joining portion 8 is the metal film, adhesiveness with the ground electrode formed of a metal can be stably secured, and hence migration can be suppressed. Of those joining portions, an amorphous silicon layer is a preferred example. The thickness of the joining portion 8 may be, for example, 0.001 μm or more and 10 μm or less, preferably 0.1 μm or more and 3 μm or less.

### EXAMPLES

The present invention is specifically described below by way of Examples. However, the present invention is not limited by these Examples.

### Example 1

### 1-1. Production of Waveguide Device 100 (Coplanar Line)

A waveguide device 100 illustrated in FIG. 3 was produced.

A polyimide substrate (resin material substrate 1) having a thickness of 0.1 mm was prepared. After surface roughening treatment was performed on a surface of the polyimide substrate, a gold film was formed by sputtering to form a ground electrode. Next, an amorphous silicon film was formed on the ground electrode by sputtering. After the film formation, the amorphous silicon film was subjected to planarization treatment by polishing. Here, the arithmetic average roughness of a □10 μm (10 μm square area; the same applies hereinafter) on the surface of the amorphous silicon film was measured with an atomic force microscope, and was found to be 0.2 nm.

In addition, a silicon wafer (support substrate) having a thickness of 525 μm was prepared. The arithmetic average roughness of the surface of a □10 μm on the surface of the silicon wafer was measured with an atomic force microscope, and was found to be 0.2 nm.

The amorphous silicon surface formed on the ground electrode and the silicon wafer were then joined in a manner described below. First, the polyimide substrate and the silicon wafer were loaded into a vacuum chamber, and joining surfaces of the two (the amorphous silicon surface formed on the ground electrode and a surface of the silicon wafer) were irradiated with a high-speed Ar neutral atom beam (acceleration voltage: 1 kV, Ar flow rate: 60 sccm) for 70 seconds in a vacuum on the order of 10⁻⁶ Pa. After the irradiation, the polyimide substrate and the silicon wafer were left to stand still for 10 minutes and cool down. The amorphous silicon surface formed on the ground electrode and the joining surface of the silicon wafer (the surfaces of the polyimide substrate and the silicon wafer that were irradiated with the beam) were brought into contact with each other, and were heated for 2 minutes at 4.90 kN to join the polyimide substrate and the silicon wafer together. That is, the polyimide substrate and the silicon wafer were directly joined to each other via an amorphous silicon layer (joining portion). After the joining, polishing processing was performed until the thickness of the silicon wafer became 200 μm. Thus, a composite wafer was formed. In the resultant polyimide substrate/ground electrode/joining portion/silicon composite substrate, no defect such as peeling was observed at the joining interface.

Then, a resist was applied to the surface (polished surface) of the polyimide substrate on the side opposite from the silicon wafer, and patterning was performed by photolithography so as to expose portions for forming a coplanar electrode pattern. The coplanar electrode pattern was then formed by sputtering on an upper surface of the polyimide substrate that was exposed from under the resist. The length of the signal electrode in the waveguide direction was 10 mm.

The waveguide device including the coplanar electrode, the resin material substrate, the ground electrode, and the support substrate was thus obtained.

### 1-2. Calculation of Propagation Loss

Then, an RF signal generator was coupled to the input side of the waveguide device with a probe, and an electromagnetic wave was coupled to an RF signal receiver placed for the probe on the output side of the waveguide device.

Then, a voltage was applied to the RF signal generator to cause the RF signal generator to transmit an electromagnetic wave having a frequency of 150 GHz. Thus, the electromagnetic wave was propagated to the coplanar line (waveguide device). The RF signal receiver measured the RF power of the electromagnetic wave output from the coplanar line. A propagation loss (dB/cm) was calculated from the measurement results, and the result of the calculation was 1 dB/cm.

### 1-3. Evaluation of Heat Dissipation Performance

The waveguide device of Example 1 was subjected to thermal conductivity analysis through use of a finite element method (FEMTET manufactured by Murata Software Co., Ltd.). In the thermal conductivity analysis, the thermal conductivity of polyimide (resin material substrate) was assumed to be 0.2 W/mK, the thermal conductivity of silicon (support substrate) was assumed to be 150 W/mK, and the thermal conductivity of gold (ground electrode) was assumed to be 300 W/mK. In Example 1, the resin material substrate and the support substrate were directly joined to each other via the ground electrode and the joining portion, and the joining interface was amorphized. Hence, the thermal interfacial resistance of the interface was set to zero. The results of the analysis found that the thermal resistance of the waveguide device was 90 K/W. Thus, an improvement in heat dissipation property by the direct joining was recognized.

### Example 2

A waveguide device was produced in the same manner as in Example 1 except that the ground electrode and the silicon wafer were directly joined to each other with use of solder (AuSn: having a thermal conductivity of 50 W/mK) in place of the amorphous silicon layer. The thermal resistance of the resultant waveguide device was analyzed in the same manner as in the above-mentioned evaluation of heat dissipation performance. As a result, the thermal resistance of the waveguide device was found to be 90 K/W.

### Comparative Example 1

A waveguide device including a coplanar electrode, a polyimide substrate, a ground electrode, a polyimide adhesive layer, and a support substrate was obtained in the same manner as in Example 1, except that the polyimide substrate on which the ground electrode was formed and the silicon wafer were adhered to each other by curing with use of a polyimide adhesive (an organic adhesive), instead of being directly joined to each other. The propagation loss of the resultant waveguide device was calculated in the same manner as in Example 1. As a result, the propagation loss was found to be 1.0 dB/cm.

In addition, the thermal resistance of the resultant waveguide device was analyzed in the same manner as in Example 1. As a result, the thermal resistance of the waveguide device was found to be 150 K/W.

The waveguide device according to the embodiments of the present invention can be used in a wide range of fields, such as waveguides, next-generation high-speed communication, sensors, laser processing, and solar power generation. In particular, the device can be suitably used as a waveguide for a millimeter wave/terahertz wave. Such a waveguide device can be used for, for example, an antenna, a band-pass filter, a coupler, a delay line (phase shifter), or an isolator.

What is claimed is:

1. A waveguide device configured to guide an electromagnetic wave having a frequency of 30 GHz or more and 20 THz or less, the waveguide device comprising:
a resin material substrate;
a conductor layer disposed on the resin material substrate; and
a support substrate disposed on a side opposite from the conductor layer with respect to the resin material substrate,
wherein the resin material substrate and the support substrate are directly joined to each other.

2. The waveguide device according to claim 1, further comprising a first ground electrode disposed between the resin material substrate and the support substrate.

3. The waveguide device according to claim 2, wherein the first ground electrode is in direct contact with the resin material substrate and the support substrate and joins the resin material substrate and the support substrate to each other.

4. The waveguide device according to claim 2,
wherein the first ground electrode is in direct contact with the resin material substrate, and
wherein the waveguide device further comprises a joining portion that joins the first ground electrode and the support substrate to each other.

5. The waveguide device according to claim 2,
wherein the first ground electrode is in direct contact with the support substrate, and
wherein the waveguide device further comprises a joining portion that joins the resin material substrate and the first ground electrode to each other.

6. The waveguide device according to claim 2, wherein the conductor layer includes:
a signal electrode which forms a transmission line configured to propagate the electromagnetic wave; and
a second ground electrode disposed at a distance from the signal electrode.

7. The waveguide device according to claim 6, further comprising:
a third ground electrode positioned on a side opposite from the first ground electrode with respect to the support substrate;
a first via which electrically connects the second ground electrode and the third ground electrode, and which is electrically connected to the first ground electrode; and
a second via which electrically connects the first ground electrode and the second ground electrode,
wherein the first via includes a plurality of first vias, and
wherein the second via is arranged between two first vias adjacent to each other out of the plurality of first vias.

8. The waveguide device according to claim 6, further comprising:
a third ground electrode positioned on a side opposite from the first ground electrode with respect to the support substrate; and
a plurality of through-substrate vias for electrically connecting the first ground electrode and the third ground electrode,
wherein the first ground electrode, the third ground electrode, and the plurality of through-substrate vias form a substrate-integrated waveguide configured to propagate the electromagnetic wave.

9. The waveguide device according to claim 1, wherein the resin material substrate has a thickness “t” which satisfies Formula (1):
$$t < \frac{λ}{a \sqrt{ε}} \qquad ( 1 )$$
where “t” represents the thickness of the resin material substrate, λ represents a wavelength of the electromagnetic wave guided by the waveguide device, c represents a relative dielectric constant of the resin material substrate at 150 GHz, and “a” represents a numerical value of 3 or more.

10. The waveguide device according to claim 9, wherein, in Formula (1), “a” represents a numerical value of 6 or more.

11. The waveguide device according to claim 1, wherein the resin material substrate has a thickness “t” which is 100 μm or less.

12. The waveguide device according to claim 1, wherein the resin material substrate has a thickness “t” which is 1 μm or more.

13. The waveguide device according to claim 1, further comprising a joining portion disposed between the resin material substrate and the support substrate,
wherein the joining portion is a SiO₂ layer, an amorphous silicon layer, or a tantalum oxide layer.
